(19) United States
(12) Patent Application Publication
(10) Pub. No.: US 2022/0359496 A1
(43) Pub. Date: Nov. 10, 2022

(54) ANTENNA DIODE CIRCUIT

(71) Applicant: TAIWAN SEMICONDUCTOR MANUFACTURING CO., LTD., Hsinchu (TW)

(72) Inventors: Sahil Preet SINGH, Bangalore (IN); Yen-Huei CHEN, Hsinchu County (TW); Hung-Jen LIAO, Hsinchu City (TW)

(73) Assignee: TAIWAN SEMICONDUCTOR MANUFACTURING CO., LTD., Hsinchu (TW)

(21) Appl. No.: 17/875,108

(22) Filed: Jul. 27, 2022

Related U.S. Application Data
(62) Division of application No. 15/799,346, filed on Oct. 31, 2017.
(60) Provisional application No. 62/538,754, filed on Jul. 30, 2017.

(51) Int. Cl. H01L 27/02; H01L 23/50; H02H 9/04

(52) U.S. Cl. CPC H01L 27/0266; H01L 27/0292; H01L 23/50; H02H 9/046; H02H 9/044

(57) ABSTRACT

A device includes a diode circuit. The diode circuit is coupled between a first input/output (I/O) pin and a second I/O pin of a circuit, and is configured to be turned off. The diode circuit is configured to provide a first discharging path for the first I/O pin of the circuit and a second discharging path for the second I/O pin of the circuit. The diode circuit includes a first transistor and a second transistor. The first transistor is between a node and the first I/O pin. The second transistor is between the node and the second I/O pin. The node is configured to receive a first voltage, and control terminals of the first transistor and the second transistor are configured to receive a second voltage. A voltage difference between the first voltage and the second voltage is configured to turn off the first transistor and the second transistor.

### RELATED APPLICATION

This application is a division of U.S. application Ser. No. 15/799,346, filed Oct. 31, 2017, which claims priority to U.S. Provisional Application Ser. No. 62/538,754, filed Jul. 30, 2017, which is herein incorporated by reference.

### BACKGROUND

Antenna effect often occurs during manufacturing of an integrated circuit. For example, the antenna effect may occur when a certain amount of electrical charges, which are introduced from certain semiconductor manufacturing processes, flows through a transistor structure into a semiconductor substrate. If the amount of electrical charges is too much, gate oxide in the transistor structure may be damaged. As a result, yield and reliability issues for an integrated circuit are decreased.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of an electronic device, in accordance with some embodiments of the present disclosure.

FIG. 2A is a schematic diagram of a layout of a circuit, in accordance with some embodiments of the present disclosure.

FIG. 2B is a schematic diagram of a schematic layout of the diode circuit in FIG. 2A, in accordance with some embodiments of the present disclosure.

FIG. 3A is a circuit diagram of the diode circuit in FIG. 1, in accordance with some embodiments of the present disclosure.

FIG. 3B is a schematic diagram of a schematic layout of the diode circuit in FIG. 3A, in accordance with some embodiments of the present disclosure.

FIG. 4A is a circuit diagram of the diode circuit in FIG. 1, in accordance with some embodiments of the present disclosure.

FIG. 4B is a schematic diagram of a schematic layout of the diode circuit in FIG. 4A, in accordance with some embodiments of the present disclosure.

FIG. 5 is a flow chart of a method, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

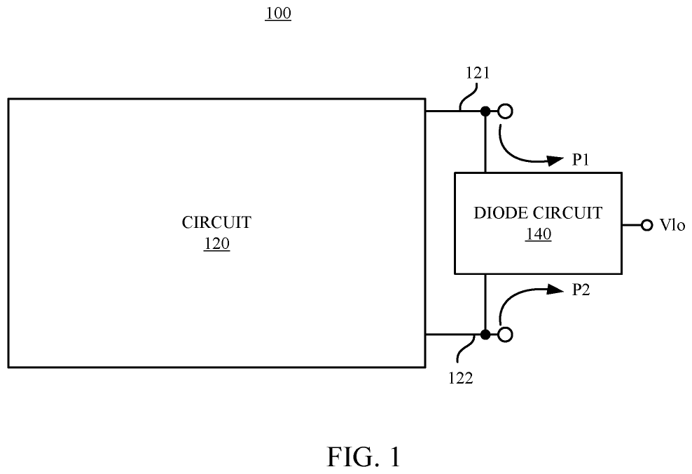

Reference is now made to FIG. 1. FIG. 1 is a schematic diagram of an electronic device 100, in accordance with some embodiments of the present disclosure. In some embodiments, the electronic device 100 is implemented as an integrated chip.

In some embodiments, the electronic device 100 includes a circuit 120 and a diode circuit 140. In some embodiments, the circuit 120 includes various active circuits formed by one or more transistors. For example, in some embodiments, the circuit 120 is a static random access memory (SRAM). As illustratively shown in FIG. 1, the circuit 120 includes two input/output (I/O) pins 121 and 122. The I/O pins 121 and 122 are configured to receive or transmit a signal (not shown).

In some conditions, excess charges may be accumulated on the I/O pins 121 and 122 during the manufacturing of the electronic device 100. For example, when a process of plasma etching is employed to fabricate the electronic device 100, the charges may be introduced from the plasma and then accumulated on the I/O pins 121 and 122. If the charges accumulated on the I/O pins 121 and 122 are too much, the I/O pins 121 and 122 may be damaged. As a result, the yield and the reliability of the electronic device 100 are reduced.

To protect the I/O pins from damage caused by the excess charges, the diode circuit 140 is arranged to be coupled between the I/O pins 121 and 122, in order to provide discharging paths P1 and P2 for discharging excess charges accumulated on the I/O pins 121 and 122. In some embodiments, the diode circuit 140 is configured to provide the discharging paths P1 and P2 while the diode circuit 140 is turned off by a voltage Vlo, in order to avoid any impact on operations of the circuit 120. The related operations will be discussed with reference to embodiments below. In some embodiments, the diode circuit 140 is referred to as “antenna diode.”

The numbers of the I/O pins shown in FIG. 1 are given for illustrative purposes. The arrangements between the circuit 120 and the diode circuit 140 are also given for illustrative purposes. Various numbers of the I/O pins operated with the diode circuit 140 and various arrangements between the circuit 120 and the diode circuit 140 are within the contemplated scope of the present disclosure. For example, in some embodiments, the diode circuit 140 is arranged to be coupled between two internal nodes (not shown) of the circuit 120.

The following paragraphs describe certain embodiments related to the diode circuit 140 to illustrate functions and applications thereof. However, the present disclosure is not limited to the following embodiments. Various arrangements to implement the functions and the operations of the diode circuit 140 in FIG. 1 are within the contemplated scope of the present disclosure.

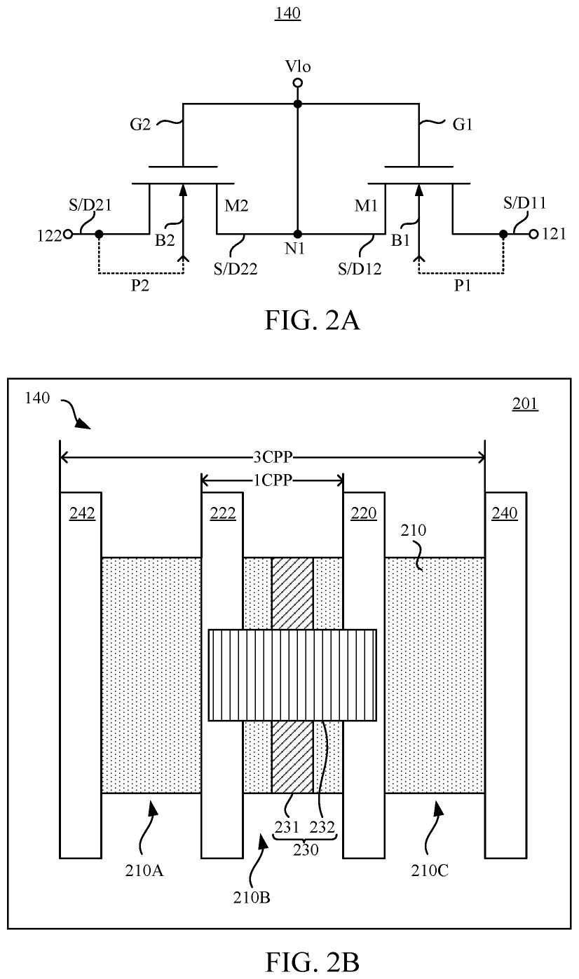

Reference is now made to FIG. 2A. FIG. 2A is a circuit diagram of the diode circuit 140 in FIG. 1, in accordance with some embodiments of the present disclosure. For ease of understanding, like elements in FIG. 2A are designated with the same reference numbers with respect to FIG. 1.

In some embodiments, the diode circuit 140 in FIG. 2 includes transistors M1 and M2. As illustratively shown in FIG. 2A, a first terminal S/D11 of the transistor M1 is coupled to the I/O pin 121, a second terminal S/D12 of the transistor M1 is coupled to a node N1 to receive the voltage Vlo, and a control terminal G1 of the transistor M1 is coupled to the second terminal S/D12 of the transistor M1. In some embodiments, the arrangement of the transistor M1 is referred to as “diode-connected transistor.” For example, the transistor M1 is implemented with an N-type MOSFET, the first terminal S/D11 and the second terminal S/D12 correspond to drain/source terminals of the transistor M1, and the control terminal G1 correspond to a gate terminal of the transistor M1. By coupling the gate terminal with one of the drain/source terminals, as shown by the transistor M1, a two-terminal diode is effectively formed by a three-terminal transistor. In some embodiments, the node N1 is configured to receive the voltage Vlo, in order to turn off the transistor M1 or M2. In some embodiments, the voltage Vlo is about 0 volts. With the arrangement of the voltage Vlo, the transistors M1-M2 are turned off. Accordingly, the transistors M1-M2 will not affect operations of the circuit 120 in FIG. 1.

The value of the voltage Vlo is given for illustrative purposes. Various values of the voltage Vlo, which are sufficient to turn off the transistors M1-M2, are within the contemplated scope of the present disclosure.

As illustratively shown in FIG. 2A, a first terminal S/D21 of the transistor M2 is coupled to the I/O pin 122, a second terminal S/D22 of the transistor M2 is coupled to the node N1 to receive the voltage Vlo, and a control terminal G2 of the transistor M2 is coupled to the second terminal S/D22 of the transistor M2. In some embodiments, the arrangement of the transistor M2 is referred to as “diode-connected transistor,” as discussed above. In some embodiments, the transistor M1 is configured to provide the discharging path P1 for charges (not shown) accumulated on the I/O pin 121. In some embodiments, the discharging path P1 is coupled between the first terminal S/D11 and a bulk terminal B1 of the transistor M1. In some embodiments, the transistor M2 is configured to provide a discharging path P2 for charges (not shown) accumulated on the I/O pin 122. In some embodiments, the discharging path P2 is coupled between the first terminal S/D21 and a bulk terminal B2 of the transistor M2. In some embodiments, the bulk terminals B1 and B2 of the transistors M1 and M2 are configured to receive a low voltage, which includes, for example, a ground voltage and/or a system low voltage (e.g., VSS).

In some embodiments, the I/O pins 121 and 122 in FIG. 2A are coupled to gates of internal transistors in the circuit 120. In some embodiments, an equivalent resistance of the gate coupled to the I/O pin 121 or 122 is much higher than an equivalent resistance of the discharging path P1 or P2. Therefore, during the manufacturing process, the excess charges (not shown) on the I/O pin 121 or 122 will flow through the discharging path P1 or P2 instead of the gate coupled to the I/O pin 121 or 122. Effectively, the gates of internal transistors in the circuit 120 are protected from being damaged by the excess discharges.

Reference is now made to FIG. 2B. FIG. 2B is a schematic diagram of a schematic layout of the diode circuit 140 in FIG. 2A, in accordance with some embodiments of the present disclosure. For ease of understanding, like elements in FIG. 2B are designated with the same reference number with respect to FIG. 2A. In some embodiments, the schematic layout of the diode circuit 140 corresponds to an actual top-view of the diode circuit 140. In some conditions, certain elements and/or structures (e.g., area 210, contact 232, etc.) in FIG. 2B may not be directly visible in the actual top view of the diode circuit 140, but it is appreciated by those skilled in the art that the diode circuit 140 in FIG. 2B may include structures, components, and/or elements beneath in the schematic layout shown in FIG. 2B.

As illustratively shown in FIG. 2B, the diode circuit 140 includes an oxide definition (OD) area 210, gate structures 220 and 222, and an interconnection structure 230. The OD area 210 is formed as an active region of the transistors M1-M2 in FIG. 2A. For illustration, in a left-to-right sequence, a portion 210A of the OD area 210 corresponds to the first terminal S/D21 of the transistor M2. A portion 210B of the OD area 210 corresponds to both of the second terminals S/D12 and S/D22 of the transistors M1-M2. A portion 210C of the OD area 210 corresponds to the first terminal S/D11 of the transistor M1. Effectively, the transistors M1-M2 are integrally formed at the OD area 210 and adjacent to each other. In some embodiments, the OD area 210 is formed on a substrate 201. In some embodiments, the OD area 210 is formed with semiconductor materials doped with various N-type of dopants, and the substrate 201 is formed with P-type semiconductor materials. In some embodiments, the substrate 201 corresponds to the bulk terminals B1 and B2 of the transistors M1-M2 in FIG. 2A.

In this example, the portions 210A and 210C are formed on and in contact with the substrate 201. Accordingly, parasitic diodes (not shown) are formed between the substrate 201 and the portions 210A and 201C, respectively, in order to form the discharging paths P1-P2 in FIG. 2A. If the charges accumulated on the I/O pins 121 and 122 in FIG. 1 are sufficient, the parasitic diode would be breakdown (or be turned on) to discharge these charges.

The gate structures 220 and 222 are formed over the OD area 210. The gate structure 220 is between the portions 210B and 210C of the OD area 210. The gate structure 222 is between the portions 210A and 210B of the OD area 210. The gate structure 220 corresponds to the control terminal G1 of the transistor M1, and the gate structure 222 corresponds to the control terminal G2 of the transistor M2. In some embodiments, the gate structures 220 and 222 are formed with metal and polysilicon. Various suitable materials to form the gate structures 220 and 222 area within the contemplated scope of the present disclosure.

The interconnection structure 230 are arranged to provide electrical connections between the gate structure 220 and the portion 210B of the OD area 210, and between the gate structure 222 and the portion 210B of the OD area 210.

In some embodiments, the interconnection structure 230 includes contacts 231-232. The contact 231 is disposed over and coupled to the portion 210B of the OD area 210. The contact 232 is formed over the gate structures 220 and 222 and the contact 231. The gate structures 220 and 222 and the contact 231 are coupled to each other via the contact 232. In other words, the contact 232 bridges the gate structures 220 and 222 and the contact 231 together. Accordingly, with the contacts 231-232, the gate structures 220 and 222 are coupled to the portion 210B of the OD area 210. Effectively, the connection between the control terminal G1 and the second terminal S/D12 of the transistor M1 and the connection between the control terminal G2 and the second terminal S/D22 of the transistor M2 in FIG. 2A are formed.

In some embodiments, the contact 231 is further coupled to a circuit (not shown) or an external signal source (not shown) via one or more contacts (not shown) and conductive segments (not shown), in order to receive the voltage Vlo in FIG. 2A. In some embodiments, the contacts 231-232 are implemented with various suitable conductive materials. In some embodiments, the contact 231 is implemented with a metal contact. In some embodiments, the contact 232 is implemented with a metal contact.

The implementations of the contacts 231-232 and the arrangements of the interconnection structure 230 are given for illustrative purposes. Various implementations of the contacts 231-232 and various arrangements of the interconnection structure 230 are within the contemplated scope of the present disclosure.

In some embodiments, the diode circuit 140 further includes dummy gate structures 240 and 242. The dummy gate structures 240 and 242 are disposed over and cover edges of the OD area 210. In some embodiments, the dummy gate structure 240 and 242 do not act as gates to any semiconductor device including, for example, the transistors M1-M2. The dummy gate structures 240 and 242 and the gate structures 220 and 222 are spaced apart from each other. In some embodiments, the dummy gate structure 240 and 242 are formed to increase the density of materials to form the gate structures 220 and 222, in order to improve the yield rate. In some embodiments, the dummy gate structures 240 and 242 are able to be omitted.

In the embodiments of FIG. 2B, a width of the diode circuit 140 is determined by the width of the OD area 210 and/or the dummy gate structures 240 and 242. In some embodiments, the width of the OD area 210 is equal to or less than about three times a distance of a poly pitch. In some embodiments, the poly pitch indicates a distance between gates. For illustration, the distance of the poly pitch is present between corresponding edges of the gate structures 220 and 222. In some embodiments, the distance of the poly pitch is defined in a design rule and/or a technology file given from a foundry.

In some embodiments, the terms “around”, “about” or “substantially” shall generally mean within 20 percent, within 10 percent, or within 5 percent of a given value or range. The ranges indicated by these terms are given for illustrative purposes. Various given values or ranges are within the contemplated scope of the present disclosure. The distance of the poly pitch defined in FIG. 2B is given for illustrative purposes. Various definitions of the distance of the poly pitch are within the contemplated scope of the present disclosure.

In some approaches, two or more separate diode circuits are employed to provide discharging paths for excess charges on different I/O pins. In these approaches, as being limited by a minimum distance between active areas defined in a design rule, the width of the diode circuits are more than or equal to seven times the distance of the poly pitch. Compared with these approaches, the width of the diode circuit 140 in FIG. 2B is much smaller. As a result, the area of a chip utilizing the diode circuit 140 is able to be saved.

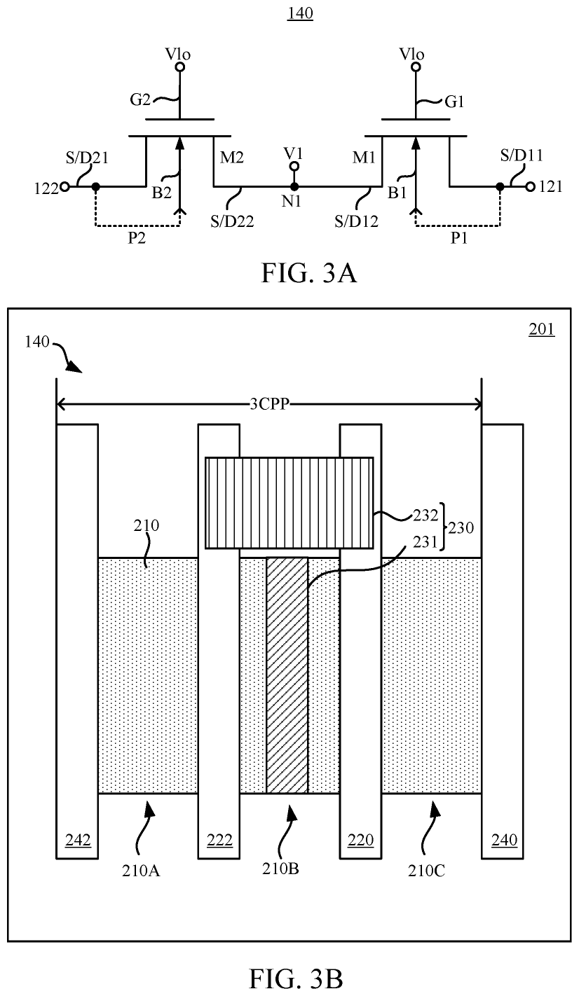

Reference is now made to FIG. 3A. FIG. 3A is a circuit diagram of the diode circuit 140 in FIG. 1, in accordance with some embodiments of the present disclosure. For ease of understanding, like elements in FIG. 3A are designated with the same reference numbers with respected to FIG. 2A.

As illustratively shown in FIG. 3A, the second terminal S/D12 of the transistor M1 and the second terminal of the S/D22 of the transistor M2 are configured to receive a voltage V1. In other words, compared with FIG. 2A, the second terminal S/D12 is not coupled to the control terminal G1, and the second terminal S/D22 is not coupled to the control terminal G2. In some embodiments, a voltage difference between the voltage V1 and the voltage Vlo is smaller than a threshold voltage of the transistors M1-M2, such that the transistors M1 and M2 are turned off by the voltage difference. In some embodiments, the voltage V1 is configured to be equal to or higher than the voltage Vlo, in order to keep the transistors M1-M2 being turned off. In some embodiments, the voltage V1 is a system high voltage (e.g., VDD). In some embodiments, the voltage V1 is a system low voltage (e.g., VSS).

In some embodiments of FIG. 3A, the transistor M1 is configured to provide the discharging path P1 for the I/O pin 121 in FIG. 1, and the transistor M2 is configured to provide the discharging path P2 for the I/O pin 122 in FIG. 1. In some embodiments of FIG. 3A, the discharging path P1 is coupled between the first terminal S/D11 and the bulk terminal B1 of the transistor M1. The discharging path P2 is coupled between the first terminal S/D21 and the bulk terminal B2 of the transistor M2.

Reference is now made to FIG. 3B. FIG. 3B is a schematic diagram of a schematic layout of the diode circuit 140 in FIG. 3A, in accordance with some embodiments of the present disclosure. For ease of understanding, like elements in FIG. 3B are designated with the same reference number with respect to FIG. 2B and FIG. 3A.

Compared with FIG. 2B, the arrangements of the interconnection structure 230 in FIG. 3B is adjusted to correspond to FIG. 3A. For illustration, the contact 232 is arranged across the gate structures 220 and 222 without coupling to the contact 231. The contact 232 is arranged to couple the gate structure 220 to the gate structure 222. In other words, the contact 232 bridges the gate structures 220 and 222 together. In some embodiments, the interconnection structure 230 in FIG. 3B further includes a conductive segment (not shown) coupled to the contact 232, and the conductive segment is further coupled to a circuit or an external signal source (not shown), in order to receive the voltage Vlo.

The contact 231 is arranged at and coupled to the portion 210B of the OD area 210. In some embodiments, the interconnection structure 230 further includes a conductive segment (not shown) coupled to the contact 231, and the conductive segment is further coupled to a circuit or an external signal source (not shown), in order to receive the voltage V1. In the embodiments of FIG. 3B, the width of the diode circuit 140 is equal to or less than about three times the distance of the poly pitch.

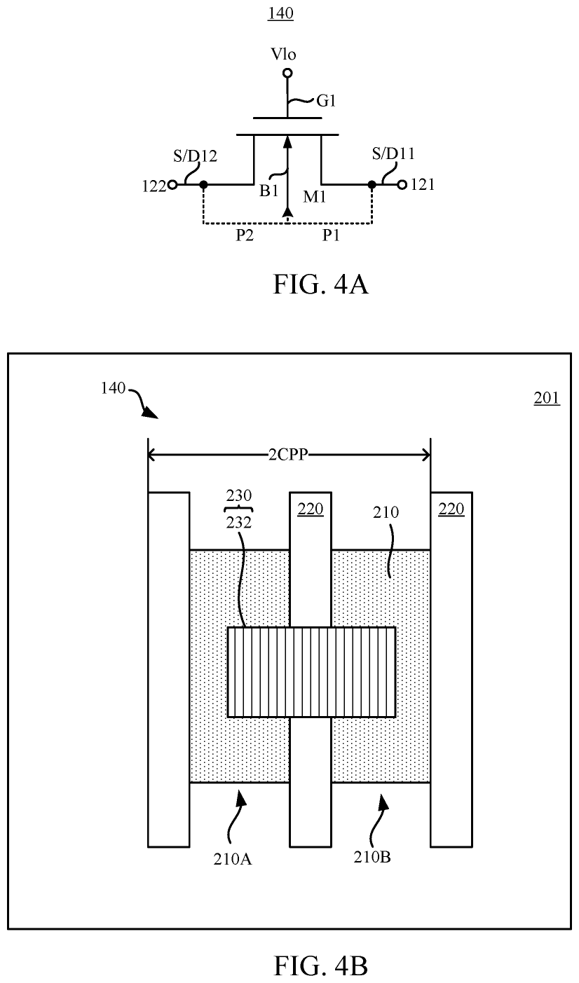

Reference is now made to FIG. 4A. FIG. 4A is a circuit diagram of the diode circuit 140 in FIG. 1, in accordance with some embodiments of the present disclosure. For ease of understanding, like elements in FIG. 4A are designated with the same reference numbers with respected to FIG. 2A.

Compared with embodiments of FIG. 2A or FIG. 3A, the diode circuit 140 in FIG. 4A only includes the transistor M1. In some embodiments of FIG. 4A, the second terminal of the transistor M1 is coupled to the I/O pin 122 in FIG. 1. In some embodiments, the first terminal S/D11 of the transistor M1 is configured to provide the discharging path P1 for the I/O pin 121. In some embodiments, the second terminal S/D12 of the transistor M1 is configured to provide the discharging path P2 for the I/O pin 122. For illustration, the discharging path P1 is coupled between the first terminal S/D11 and the bulk terminal B1 of the transistor M1, and the discharging path P2 is coupled between the second terminal S/D12 and the bulk terminal B2 of the transistor M1.

Reference is now made to FIG. 4B. FIG. 4B is a schematic diagram of a schematic layout of the diode circuit 140 in FIG. 4A, in accordance with some embodiments of the present disclosure. For ease of understanding, like elements in FIG. 3B are designated with the same reference number with respect to FIG. 2B and FIG. 3A.

Compared with embodiments of FIG. 2B or FIG. 3B, the arrangements of the OD area 210 and the interconnection structure 230 in FIG. 4B are adjusted to correspond to FIG. 4A. For illustration, as shown in FIG. 4B, the diode circuit 140 only includes the gate structure 220 and the contact 232, and the OD area 210 thereof only includes the portions 210A and 210B. The gate structure 220 is formed over the OD area 210 and between the portions 210A and 210B, and corresponds to the control terminal G1 in FIG. 4A. The portion 210A of the OD area 210 corresponds to the second terminal S/D12 of the transistor M1 in FIG. 4A. In some embodiments, the portion 210A may be coupled to the I/O pin 122 through contacts (not shown) and/or conductive segments (not shown). The portion 210B of the OD area 210 corresponds to the first terminal S/D11 of the transistor M1 in FIG. 4A. In some embodiments, the portion 210B may be coupled to the I/O pin 121 through contacts (not shown) and/or conductive segments (not shown).

The contact 232 is arranged with respect to the gate structure 220. The contact 232 is arranged to be coupled the gate structure 220. In some embodiments, the interconnection structure 230 further includes a conductive segment (not shown) coupled to the contact 232, and the conductive segment is further coupled to a circuit or an external signal source (not shown), in order to receive the voltage Vlo.

In this example, the portions 210A and 210C are formed on and in contact with the substrate 201. Accordingly, parasitic diodes (not shown) are formed between the substrate 201 and the portions 210A and 201C, respectively, in order to form the discharging paths P1-P2 in FIG. 2A. If the charges accumulated on the I/O pins 121 and 122 in FIG. 1 are sufficient, the parasitic diode would be breakdown (or be turned on) to discharge these charges.

In the embodiments of FIG. 4B, the width of the diode circuit 140 is equal to or less than about two times the distance of the poly pitch. Compared with the embodiments of FIG. 2B or FIG. 3B, the width of the diode circuit 140 is able to be further reduced.

For ease of understanding, transistors M1-M2 in the embodiments discussed above are shown with N-type transistors. It is appreciated by those skilled in the art that the embodiments discussed above are able to be implemented with P-type transistors. For example, on condition that the transistors M1-M2 discussed above are implemented with P-type transistors, the bulk terminals thereof may correspond to an N-well on the substrate, and the voltages Vlo and/or V1 discussed above are correspondingly adjusted to be sufficient to turn off the transistors M1-M2. Various types of transistors to implement the embodiments discussed above are within the contemplated scope of the present disclosure.

The interconnection structure 230 shown in FIGS. 2B, 3B, and 4B are given for illustrative purpose. The implementations and the arrangements of the interconnection structure 230 are able to be adjusted, replaced, or changed, without departing from the spirit and scope of the present disclosure, according to actual process technology. Accordingly, various implementations and various arrangements of the interconnection structure 230 are within the contemplated scope of the present disclosure.

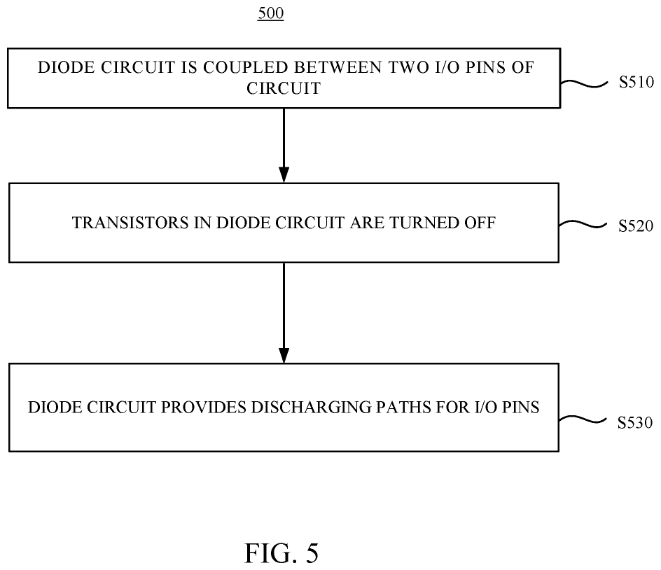

FIG. 5 is a flow chart of a method 500, in accordance with some embodiments of the present disclosure. For ease of understanding, reference is now made to FIG. 2A and FIG. 5, and operations of the method 500 are described with the diode circuit 140. In some embodiments, the method 500 includes operations S510, S520, and S530.

In operation S510, a diode circuit is coupled between two I/O pins of a circuit. For illustration, as discussed in FIG. 1 above, the diode circuit 140 is arranged to be coupled between the I/O pins 121 and 122 of the circuit 120.

In operation S520, transistors of the diode circuit are configured to be turned off. For illustration, as discussed in FIG. 2A, the control terminals G1-G2 and the second terminals S/D12 and S/D22 of the transistors M1-M2 are arranged to receive the same voltage Vlo, such that the transistors M1-M2 of the diode circuit 140 are kept being turned off. In some alternative examples as discussed in FIG. 3A, the control terminals G1-G2 of the transistors M1 and M2 are arranged to receive the voltage Vlo, and the second terminals S/D12 and S/D22 of the transistors M1 and M2 are configured to receive the voltage V1. The transistors M1 and M2 are configured to be kept being turned off by the voltage difference between the voltage Vlo and the voltage V1. In some further examples as discussed in FIG. 4A, the transistor M1 can be kept being turned off by the voltage Vlo while the first terminal S/D11 and the second terminal S/D12 are coupled between the I/O pins 121 and 122. With operation S520, operations of the circuit 120 will not be affected by the diode circuit 140.

With continued reference to FIG. 5, in operations S530, the diode circuit provides discharging paths for the I/O pins of the circuit. For illustration, as discussed in FIG. 2A and FIG. 3A above, the transistor M1 provides the discharging path P1 for the I/O pin 121. The discharging path P1 is coupled between the I/O pin 121 and the bulk terminal B1 of the transistor M1, in order to bypass the excess discharges accumulated on the I/O pin 121. The transistor M2 provides the discharging path P2 for the I/O pin 122. The discharging path P2 is coupled between the I/O pin 122 and the bulk terminal B2 of the transistor M2, in order to bypass the excess discharges accumulated on the I/O pin 122. Alternatively, in some other embodiments of FIG. 4A, the discharging paths P1-P2 are provided by the transistor M1. In FIG. 4A, the discharging path P1 is coupled between the I/O pin 121 and the bulk terminal B1, and the discharging path P2 is coupled between the I/O pin 122 and the bulk terminal B1.

The above description of the method 500 includes exemplary operations, but the operations of the method 500 are not necessarily performed in the order described. The order of the operations of the method 500 disclosed in the present disclosure are able to be changed, or the operations are able to be executed simultaneously or partially simultaneously as appropriate, in accordance with the spirit and scope of various embodiments of the present disclosure.

As described above, the diode circuits discussed herein are able to provide discharging paths for the circuit without affecting operations of the circuit. Moreover, the diode circuits discussed herein are able to be implemented in a small chip size. Accordingly, cost of a device that utilizes the diode circuits discussed herein can be saved.

In this document, the term “coupled” may also be termed as “electrically coupled,” and the term “connected” may be termed as “electrically connected”. “Coupled” and “connected” may also be used to indicate that two or more elements cooperate or interact with each other.

In some embodiments, a device is disclosed, and the device includes a diode circuit. The diode circuit is on a substrate and coupled between a first input/output (I/O) pin and a second I/O pin of a circuit, and is configured to be turned off. The diode circuit is configured to provide a first discharging path for the first I/O pin of the circuit and a second discharging path for the second I/O pin of the circuit. The diode circuit includes a first transistor and a second transistor. The first transistor is coupled between a node and the first I/O pin. The second transistor is coupled between the node and the second I/O pin. The node is configured to receive a first voltage, and a control terminal of the first transistor and a control terminal of the second transistor are configured to receive a second voltage, wherein a voltage difference between the first voltage and the second voltage is configured to turn off the first transistor and the second transistor.

Also disclosed is a device is disclosed, and the device includes a diode circuit. The diode circuit is coupled between a first input/output (I/O) pin and a second I/O pin of a circuit, and is configured to be turned off. The diode circuit is configured to provide a first discharging path for the first I/O pin of the circuit and a second discharging path for the second I/O pin of the circuit. The diode circuit includes a transistor coupled between the first I/O pin and the second I/O pin. A control terminal of the transistor is configured to receive a voltage, in order to turn off the transistor.

Also disclosed is a method that includes operations below. One or more transistors, which are formed at an active region and adjacent to each other, is coupled between a first input/output (I/O) pin and a second I/O pin of a circuit. The one or more transistors is turned off to provide a first discharging path for the first I/O pin and to provide a second discharging path for the second I/O pin. The one or more transistors include a first transistor and a second transistor. A first voltage is transmitted to a first terminal of the first transistor and a first terminal of the second transistor. A second voltage is transmitted to a control terminal of the first transistor and a control terminal of the second transistor, in order to turn off the first transistor and the second transistor by a voltage difference between the first voltage and the second voltage. A second terminal of the first transistor is coupled to the first I/O pin, and a second terminal of the second transistor is coupled to the second I/O pin.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a diode circuit on a substrate and coupled between a first input/output (I/O) pin and a second I/O pin of a circuit, and configured to be turned off,
wherein the diode circuit is configured to provide a first discharging path for the first I/O pin of the circuit and a second discharging path for the second I/O pin of the circuit,
wherein the diode circuit comprises:
a first transistor coupled between a node and the first I/O pin; and
a second transistor coupled between the node and the second I/O pin,
wherein the node is configured to receive a first voltage, and a control terminal of the first transistor and a control terminal of the second transistor are configured to receive a second voltage, wherein a voltage difference between the first voltage and the second voltage is configured to turn off the first transistor and the second transistor.

2. The device of claim 1, wherein the first discharging path is from the first I/O pin to a bulk terminal of the first transistor for discharging excess charges accumulated on the first I/O pin, and the second discharging path is from the second I/O pin to a bulk terminal of the second transistor for discharging excess charges accumulated on the second I/O pin.

3. The device of claim 1, wherein the first voltage is higher than the second voltage.

4. The device of claim 1, wherein the first I/O pin is coupled to gates of internal transistors, and an equivalent resistance of the gate coupled to the first I/O pin is higher than an equivalent resistance of the first discharging path.

5. The device of claim 1, wherein the first transistor and the second transistor comprise:
an active region comprising a first portion, a second portion, and a third portion, wherein the second portion of the active region corresponds to the node;
a first gate structure over the active region and between the first portion and the second portion of the active region, and configured to operate as the control terminal of the first transistor;
a second gate structure over the active region and between the second portion and the third portion of the active region, and configured to operate as the control terminal of the second transistor; and
an interconnection structure coupling the first gate structure to the second gate structure.

6. The device of claim 5, wherein the interconnection structure comprises a first contact and a second contact, the first contact is coupled to the second portion, the second contact couples the first gate structure to the second gate structure, and the second contact is without coupling to the first contact.

7. The device of claim 6, wherein the second contact and the first gate structure are in different layers.

8. The device of claim 6, wherein the first gate structure and the second gate structure are between the substrate and the second contact.

9. The device of claim 5, wherein a width of the diode circuit is equal to or less than about three times a distance between the first gate structure and the second gate structure.

10. A device, comprising:
a diode circuit on a substrate and coupled between a first input/output (I/O) pin and a second I/O pin of a circuit, and configured to be turned off,
wherein the diode circuit is configured to provide a first discharging path for the first I/O pin of the circuit and a second discharging path for the second I/O pin of the circuit,
wherein the diode circuit comprises:
a transistor coupled between the first I/O pin and the second I/O pin,
wherein a control terminal of the transistor is configured to receive a voltage, in order to turn off the transistor.

11. The device of claim 10, wherein the first discharging path is from the first I/O pin to a bulk terminal of the transistor for discharging excess charges accumulated on the first I/O pin, and the second discharging path is from the second I/O pin to the bulk terminal of the transistor for discharging excess charges accumulated on the second I/O pin.

12. The device of claim 10, wherein the transistor comprises:
an active region comprising a first portion and a second portion;
a gate structure over the active region and between the first portion and the second portion of the active region, and configured to operate as the control terminal of the transistor; and
an interconnection structure transmitting the voltage to the gate structure.

13. The device of claim 12, wherein the interconnection structure comprises a contact, the contact couples the gate structure, and the contact and the gate structure are in different layers.

14. The device of claim 13, wherein the gate structure is between the substrate and the contact.

15. The device of claim 10, wherein a width of the diode circuit is equal to or less than about two times a distance of a poly pitch.

16. A method, comprising:
coupling one or more transistors, which are integrally at an active region and adjacent to each other, between a first input/output (I/O) pin and a second I/O pin of a circuit; and
turning off the one or more transistors, in order to provide a first discharging path for the first I/O pin and to provide a second discharging path for the second I/O pin,
wherein the one or more transistors comprise a first transistor and a second transistor, and turning off the one or more transistors comprises:
transmitting a first voltage to a first terminal of the first transistor and a first terminal of the second transistor; and
transmitting a second voltage to a control terminal of the first transistor and a control terminal of the second transistor, in order to turn off the first transistor and the second transistor by a voltage difference between the first voltage and the second voltage,
wherein a second terminal of the first transistor is coupled to the first I/O pin, and a second terminal of the second transistor is coupled to the second I/O pin.

17. The method of claim 16, wherein the first transistor and the second transistor comprise:
an active region comprising a first portion, a second portion, and a third portion, wherein the second portion of the active region corresponds to the first terminal of the first transistor and the first terminal of the second transistor;
a first gate structure over the active region and between the first portion and the second portion of the active region, and configured to operate as the control terminal of the first transistor;
a second gate structure over the active region and between the second portion and the third portion of the active region, and configured to operate as the control terminal of the second transistor; and
an interconnection structure coupling the first gate structure to the second gate structure.

18. The method of claim 17, wherein the interconnection structure comprises a first contact and a second contact, the first contact is coupled to the second portion, the second contact couples the first gate structure to the second gate structure, and the second contact is without coupling to the first contact.

19. The method of claim 16, wherein the first voltage is higher than the second voltage.

20. The method of claim 16, wherein the first discharging path is from the first I/O pin to a bulk terminal of the first transistor for discharging excess charges accumulated on the first I/O pin, and the second discharging path is from the second I/O pin to a bulk terminal of the second transistor for discharging excess charges accumulated on the second I/O pin.
